(19) United States
(12) Patent Application Publication
(10) Pub. No.: US 2006/0043479 A1
(43) Pub. Date: Mar. 2, 2006

(54) Metal oxide semiconductor device including a shielding structure for low gate-drain capacitance

(76) Inventors: Patrice Parris, Phoenix, AZ (US); Edouard D. de Fresart, Tempe, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/933,052

(22) Filed: Sep. 2, 2004

(51) Int. Cl. H01L 29/76

(52) U.S. Cl. 257/341

(57) ABSTRACT

A semiconductor MOSFET device (70, 100), and method of fabricating the device, including a shielding structure (86, 210) for decreasing the gate-drain capacitance (C_{GD}) without simultaneously increasing the gate resistance or the total device ON-state resistance (R_{DSON}). The shielding structure (86, 210) is formed between a drain region (76, 106) and an active gate electrode (88, 118) in the form of a separate dummy gate (87) or a trench (212) having a material (214) formed therein. The shielding structure (86, 210) forms a capacitance “shield” between the gate (88, 118) and drain region (76, 106). The MOSFET device (70, 100) further includes a semiconductor material (74, 104) defining therein a drain region (76, 106), at least one body region (78, 108) formed in the semiconductor material (74, 104), at least one source region (80, 110) formed in each body region (78, 108), and an active gate electrode (88, 118) formed over the semiconductor material (74, 104).

### BACKGROUND

1. Field of the Invention

The present disclosure relates to power MOSFETs and method of manufacture, and more specifically to a novel power MOSFET including a shielding structure that provides for low gate-drain capacitance (C_{GD}), thereby improving high frequency switching.

2. Description of the Related Art

Discrete MOSFETs are increasingly being used in applications where high frequency switching is sought. Several components of capacitance determine the maximum frequency of switching for a given MOSFET structure. One of the most important components is the gate-drain capacitance (C_{GD} or CR_{SS}). FIG. 1 illustrates a conventional vertical MOSFET structure 10, including a gate electrode 12, a plurality of body regions 13, a source 14, a drain 16, and a gate oxide material 18 having a thickness indicated by “x”. The primary determinants of gate-drain capacitance (C_{GD}) are the thickness “x” of the gate oxide 12, the drain 16 doping profile, and the spacing between adjacent body regions 13. Both are usually specified by other device parametric criteria. The minimum gate oxide thickness allowed must be sufficient to reliably sustain the expected gate voltage bias. The drain doping must be set to retard the onset of high junction field effect transistor (JFET) resistance during device operation.

The need to reduce gate-drain capacitance (C_{GD}) in MOSFET devices has led to several recent proposals, for example: i) increasing the gate oxide thickness; ii) increasing the thickness of the oxide directly under the gate electrode and over the drain region; iii) decreasing drain doping close to the silicon surface; and iv) splitting the gate electrode. The first recent proposal for reducing gate-drain capacitance (C_{GD}) discloses increasing the gate oxide thickness, as illustrated in a device 20 of FIG. 2. The increasing of the oxide between a gate electrode 22 and a drain region 26, provides for a decrease in the gate-drain capacitance (C_{GD}) in addition to other capacitances, like gate-source capacitance (C_{GS}). As illustrated in FIG. 2, device 20 includes gate electrode 22, a source 24, drain region 26, and a gate oxide 28, having a thickness “x”. Increasing the gate oxide 28 thickness “x” will also raise the threshold voltage, V_{T}, of the MOSFET device 20, thereby increasing its ON-state channel resistance. If the channel resistance is a significant percentage of the total device resistance, this increase will result in an unwanted noticeable increase in the total device ON-state resistance (R_{DSON}). Minimizing the R_{DSON} is often one of the most important tasks in designing a power MOSFET.

The second recent proposal for decreasing gate-drain capacitance (C_{GD}) is illustrated in FIG. 3 and provides for a device 30 having an increase in the thickness of an oxide 38 directly under a gate electrode 32, and over a drain region 36. By increasing the oxide thickness only over drain region 36, the channel resistance can be held constant while the gate-drain coupling (C_{GD}) is reduced. This increasing of the oxide thickness over drain region is accomplished with either a field oxide plug, as illustrated in FIG. 3, or a terraced gate oxide as illustrated in FIG. 4. Both approaches work but have limitations, and become less effective as process lithography shrinks. In the case of a field oxide plug 39 as illustrated in FIG. 3, the body-to-body spacing which can be achieved is limited by the “bird's beak” encroachment of plug 39. In addition, the thermal budget necessary to grow the field oxide will make it harder to maintain the more sophisticated profiles of modern optimized devices if the field oxidation is not done prior to implantation.

As illustrated in FIG. 4, a device 40, including a gate electrode 42, a source 44, a drain region 46, and a terraced oxide 48, also has limitations. In general, there are two ways to create terraced oxide 48, use CMOS-like, double-gate oxide (DGO) formation, or a deposited dielectric plug. In the first method, an oxide is grown on the entire substrate surface and then etched so that oxide remains only over the drain area at the semiconductor surface. The next step is to perform a second oxidation. After the second oxidation, the oxide over the drain area is thicker and the oxide over the body and body-drain junction areas is the gate oxide. As the body-to-body spacing decreases, there is an increase in the propensity for, and impact of, an oxide under cut during the masked etches. This limits the use of this technique at smaller lithography nodes. The technique differs from conventional DGO formation. In conventional DGO formation, entire transistors are either covered with photoresist or exposed to an etch step, depending on the oxide thickness desired. The differential between the two thicknesses is set, in part, by the thickness of the initial oxide. Therefore, creating a large differential means a thick initial oxide and long thermal cycle.

The second method decreases the thermal budget for terraced oxide formation by using a deposited oxide. The process can be “deposition first” or “deposition last”. In the former, the first step include depositing an oxide (or other dielectric) on the semiconductor surface and then etching the oxide so that the body and body-drain junction areas are free of deposited oxide. The subsequent thermal cycle grows the gate oxide and densifies the deposited oxide. The densification process will cause the thickness of the deposited oxide to decrease, lessening the differential between it and the gate oxide. If the oxidation proceeds for enough time, the plug region will contain a stack having a densified deposited oxide and a thermal oxide. Again, the masked etch step starts to become limited as the body-to-body separation decreases, so that the deposited oxide thickness, and oxide differential, must decrease. In the “deposition last” method the thermal oxidation is done first and then followed by an oxide (or other dielectric) deposition and masked etch. Eliminating exposure of the deposited oxide to the gate oxidation cycle, results in less densification and loss of oxide differential. However, the presence of the masked etch can again limit the minimum body-to-body separation. In addition, the gate oxide is now exposed to the oxide (or other dielectric) etch (wet or RIE) used to remove the excess deposited oxide. This step can have a serious impact on reliability of the gate oxide, introduces a new source of variation in gate oxide thickness, and limits the minimum thickness of a gate oxide.

Another example of a recently proposed structure for decreasing gate-drain capacitance (C_{GD}) provides for decreasing drain doping close to the silicon surface as illustrated in the device referenced FIG. 5. As illustrated, a device 50, including a gate electrode 52, a source 54, a drain region 56, and a gate oxide 58, provides for lower drain doping which results in a larger depletion region at the semiconductor surface. The lower doping near the semiconductor surface forces a wider body-to-body pitch, as indicated by the solid lines and reference arrows 2, relative to arrows 1, in order to maintain low JFET resistance. In order to prevent the larger depletion region from causing a significant increase in total device ON-state resistance (R_{DSON}), the body regions need to be moved further apart. The result is an increase in the total device ON-state resistance (R_{DSON}).

Yet another recently proposed structure for lowering gate-drain capacitance (C_{GD}) in a MOSFET device, as previously stated, includes splitting the gate electrode. FIGS. 6 and 7 illustrate this solution. To create the configuration shown in FIG. 6, provided is device 60, including a split gate electrode 62, a gate oxide 63, a source 64, and a drain 66. Gate material 62 and 63, as illustrated, is removed from a portion of the semiconductor surface over drain region 66. This causes an increase in the transistor gate resistance and may result in significant debiasing and turn-on effects in large transistors with long, thin gate fingers. In addition, illustrated by the dashed lines in FIG. 6 is the exposing of the semiconductor surface to the fringing fields, from gate electrode 62. These fields will increase in intensity with the use of tighter lithography to increase channel density, thereby increasing the unwanted gate-drain capacitance.

As illustrated in FIG. 7, wherein similar numbers have a prime added to indicate a different known embodiment from that illustrated in FIG. 6, the fringing fields from gate 62′ to drain 66′ are decreased by placing a dummy gate electrode 68 between the two real gate electrodes 62′. The dummy gate 68 is electrically connected to source 64′ of transistor 60′, normally at ground potential in low-side configurations. However, the use of dummy gate 68 does not improve the gate resistance since the real gate electrodes 62′ remain unchanged from those in FIG. 6.

Manufacturers are continuing to seek new means of producing power MOSFET devices, capable of increasingly high switching frequencies beyond these known devices. In order to allow for this it would be advantageous to have a MOSFET that provides for the inclusion of a means for decreasing the gate-drain capacitance, without simultaneously increasing the gate resistance or the total device ON-state resistance (R_{DSON}) like many of the above described prior art device solutions.

### SUMMARY OF THE DISCLOSURE

According to the present disclosure, disclosed is a semiconductor device and method of fabricating the device, including a semiconductor material, a drain region, at least one body region formed in the semiconductor material. At least one source region is formed in each body region, and a gate electrode is formed over the surface of the semiconductor material. An insulation layer, such as a gate oxide material, insulates the gate electrode from the semiconductor layer. To reduce gate-drain capacitance, a shielding structure is formed between the drain region and gate electrode in the form of one of a dummy gate or a trench having an insulative material formed therein. The shielding structure forms a “shield” for the capacitance between the gate and drain, thereby decreasing the gate-drain capacitance without simultaneously increasing the gate resistance or the total device ON-state resistance (R_{DSON}).

### BRIEF DESCRIPTION OF THE DRAWINGS

The foregoing and further and more specific objects and advantages of the instant disclosure will become readily apparent to those skilled in the art from the following detailed description of the preferred embodiments thereof taken in conjunction with the drawings, in which:

FIGS. 1-7 are simplified cross-sectional views of a plurality of MOSFET devices according to prior art;

FIG. 8 is a simplified cross-sectional view of a MOSFET device according to a first embodiment of the present invention; and

FIG. 9 is a simplified cross-sectional view of a MOSFET device according to a second embodiment of the present invention.

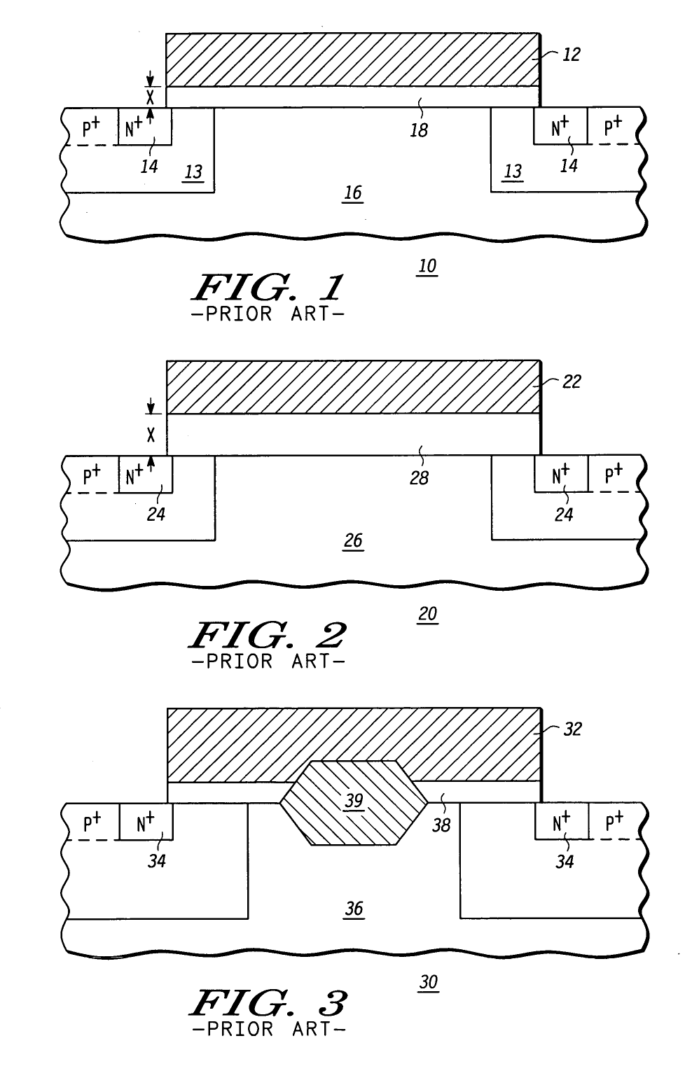

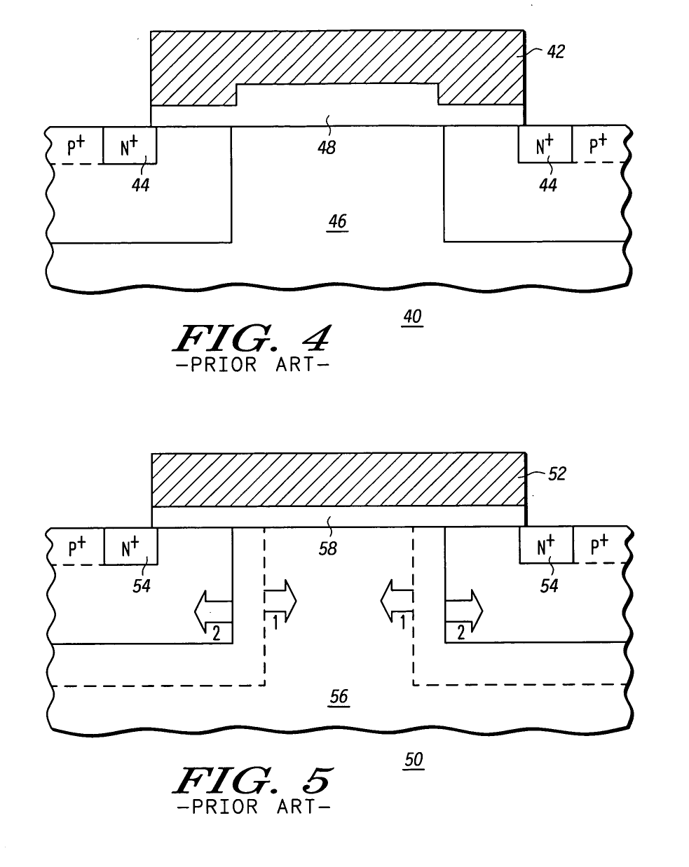

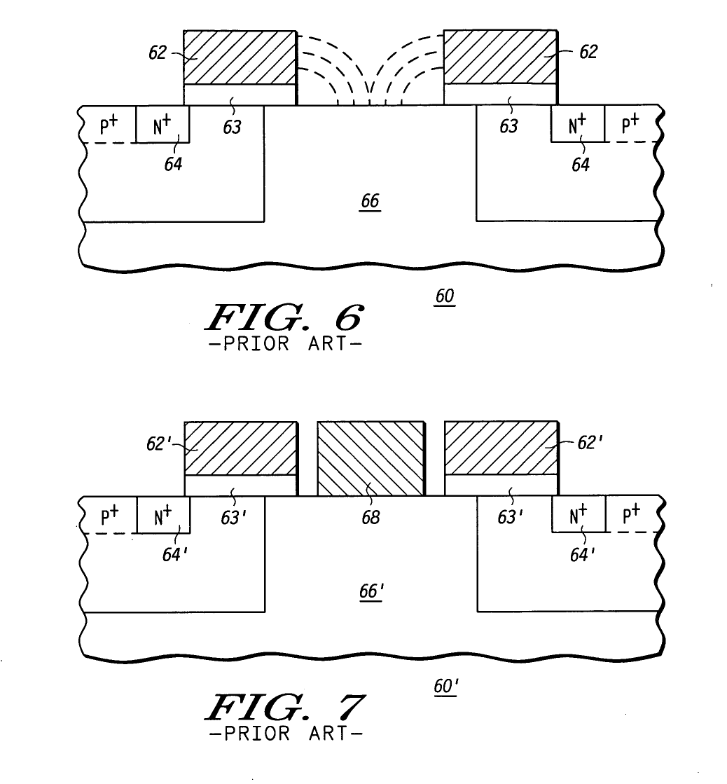

### DETAILED DESCRIPTION

The present disclosure will now be described more fully hereinafter with reference to the accompanying drawings, in which preferred embodiments of the disclosure are shown. These embodiments are provided so that this disclosure will be thorough and complete, and will fully convey the scope of the disclosure to those skilled in the art. It should be understood that it this disclosure may, be embodied in different forms and should not be construed as limited to the embodiments set forth herein.

The goal of the present disclosure is to provide for decreased gate-drain capacitance (C_{GD}) in a power MOSFET device without impacting the gate resistance or having a significant impact on total device ON-state resistance (R_{DSON}). In addition, it is desired to achieve substantial decoupling of the transistor gate and drain while retaining the low gate resistance of the original transistor structure. Alternative structures or means, in the form of two embodiments, are disclosed for accomplishing these goals. In a first embodiment, dual gate structures are formed, wherein one gate serves as a “dummy gate” and provides for the isolation of the active gate from the semiconductor material. In the second embodiment, unconventional use of trench isolation achieves isolation of the gate structure from the bulk of the semiconductor material, and more specifically the drain region.

According to an embodiment of the present disclosure, a power MOSFET device is capable of increasingly high switching frequencies by providing a means for reducing the gate-drain capacitance (C_{GD}).

According to an embodiment of the present disclosure, a power MOSFET device is capable of simultaneously reducing gate-drain capacitance (C_{GD}) without causing a significant increase in total device ON-state resistance (R_{DSON}).

According to an embodiment of the present disclosure, a power MOSFET device provides for a means for reducing gate-drain capacitance (C_{GD}) independently of the device gate oxide thickness.

According to an embodiment of the present disclosure, a power MOSFET device provides for a means for reducing gate-drain capacitance (C_{GD}) independently of the device drain doping profile.

Referring now to FIG. 8, illustrated is a simplified cross-sectional view of a MOSFET device 70 according to a first embodiment of the present invention. Device 70 is formed of a semiconductor substrate 72, having a semiconductor material 74, formed thereon one surface. Substrate 72 and semiconductor material 74 are doped dependent upon conductivity sought for the device. For a N-channel device, to produce N-type conductivity, substrate 72 comprises a heavily doped N-type substrate and semiconductor material 74 comprises a more lightly doped N-type material. A drain region 76 is formed in semiconductor material 74. A first body region of a second conductivity type 78 and a second body of a second conductivity type 78, spaced apart from first body region 78, are formed in semiconductor material 74. In this particular embodiment, first and second body regions 78 are P-type doped.

A first source region 80 and a second source region 80 are formed in first body region 78 and second body region 78 respectively. First source region and second source region 80 are heavily doped N-type conductivity sources. A first contact region 82 of the second conductivity, which in this embodiment is P-type, is formed in first body region 78, and a second contact region 82, also formed of a second conductivity type, is formed in second body region 78. It should be understood that although the preferred embodiments disclosed herein include first and second body regions, source regions, and contact regions, anticipated by this disclosure is a device including one body region, one source region, and one contact region. In addition, inclusion of the contact region is optional dependent upon device parameters. For purposes of describing the preferred embodiments, a plurality of body regions, source regions, and contact regions are described.

A gate structure 84 is formed over an uppermost surface 77 of semiconductor material 74. In this particular embodiment, gate structure 84 is comprised of overlapping conductive gate structures, and more specifically a shielding structure 86 and an active tiered gate structure 88. Shielding structure 86 in this particular embodiment is formed as a dummy gate 87. An insulation layer 90 generally formed of an oxide, insulates gate structure 84 from semiconductor material 74. A portion 94, of insulation layer 90, as illustrated, isolates shielding structure 86, and more particularly the dummy gate structure 87, from active tiered gate structure 88 which surrounds shielding structure 86.

Gate structure 84, comprised of the overlapping conductive gate structures, provides for an underlying shield, in the form of dummy gate 87, which can be biased to help decrease total device ON-state resistance (R_{DSON}). This type of structure provides for the “shielding” of capacitance between active gate structure 88 and drain region 76, and thereby decreases the gate-drain capacitance (C_{GD}), without an increase in the total device ON-state resistance (R_{DSON}). It is anticipated by this disclosure that in this first preferred embodiment that overlapping conductive gate structure 84 will provide for a typical decrease in gate-drain capacitance from approximately 700 pF to approximately 200 pF at 12V VDS and a decrease in gate-charge from approximately 60 nC to approximately 25 nC at 4.5V VGS.

In this first preferred embodiment, device 70 is formed in a two-part polysilicon deposition process. It should however be understood that alternative deposition processes are anticipated by this disclosure for the fabrication of device 70. In a first deposition step, shielding structure 86, or dummy gate 87, is deposited on top of insulation layer 90 before fabrication of gate 88. Dummy gate 87 is patterned so that it does not overlap the junction 92 between drain region 76 and body regions 78. Insulation layer 94 is grown or deposited over the shielding structure 86, subsequent to patterning. In a preferred embodiment, dummy gate 87 is formed of polysilicon, but it is anticipated by this disclosure that dummy gate 86 can be formed of any type of conductive material, including metal, polycides, semiconductive material, or the like. Once this step is complete, gate structure 88 is deposited and patterned so that it overlaps junction 92 between drain region 76 and body regions 78. In order to realize the lowest possible total device ON-state resistance (R_{DSON}), some overlap of the drain-body junction 92 by gate structure 88 is required, even though this overlap inevitably leads to some gate-drain capacitance (C_{GD}), and therefore should be minimal. The remaining layers of device 70 are formed according to standard conventional MOSFET fabrication. In this particular embodiment, gate structure 88 is tiered in design. Gate structure 88 provides for a decrease in gate-drain capacitance (C_{GD}) without splitting into smaller fingers, therefore gate-resistance is not increased. Shielding structure 86, and more particularly dummy gate 87, optionally connects to source regions 80, which are normally ground in low-side configurations.

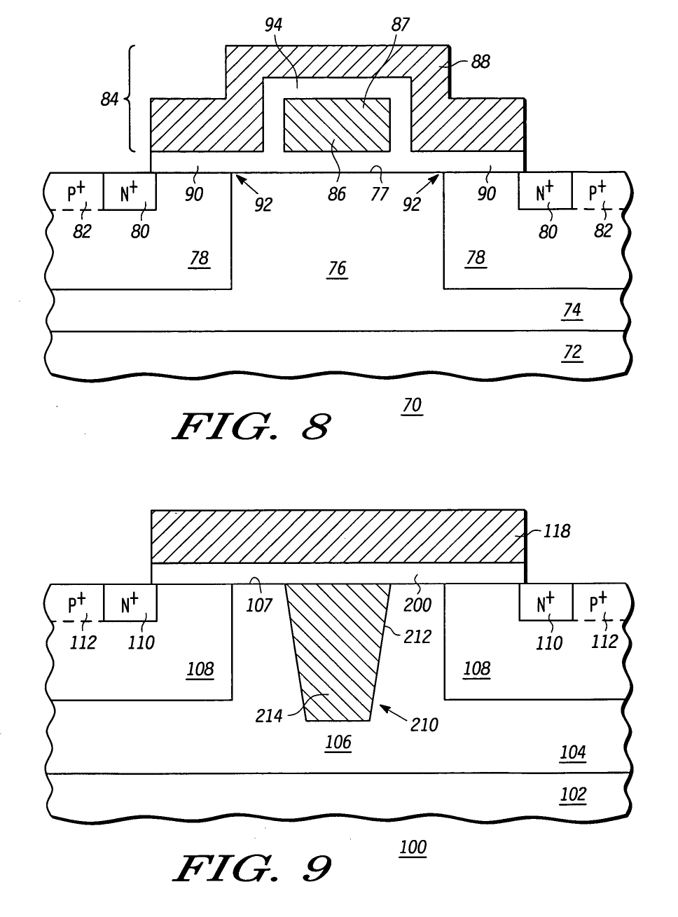

Referring now to FIG. 9, illustrated is a simplified cross-sectional view of a MOSFET device 100 according to a second preferred embodiment of the present invention. Device 100 includes an optional semiconductor substrate 102, having a semiconductor material 104, formed thereon one surface. Substrate 102 and semiconductor material 104 are formed of well-known semiconductor materials and doped dependent upon conductivity sought for the device. For a N-channel device, to produce N-type conductivity, substrate 102 comprises a heavily doped N-type substrate and semiconductor material 104 comprises a more lightly doped N-type layer. A drain region 106 is formed in semiconductor material 104. A first body region of a second conductivity type 108 and a second body of a second conductivity type 108, spaced apart from first body region 108, are formed in semiconductor material 104. In this particular embodiment, first and second body regions 108 are P-type doped.

A first source region 110 and a second source region 110 are formed into first body region 108 and second body region 108 respectively. First source region 110 and second source region 110 are heavily doped N-type conductivity sources. A first contact region 112 of the second conductivity, which in this embodiment is P-type, is formed in first body region 108, and a second contact region 112, also formed of a second conductivity type, which in this particular embodiment is P-type, is formed in second body region 108. It should be understood that anticipated by this disclosure is a device including a single body region, a single source region, and a single contact region. In addition, inclusion of the contact region is optional dependent upon device parameters. For purposes of description, this second preferred embodiment includes a plurality of body regions, source regions, and contact regions.

A gate structure 118 is formed over an uppermost surface of semiconductor material 104. In this particular embodiment, gate structure 118 is formed as a standard polysilicon active gate. Gate structure 118 is insulated from semiconductor material 104 by an insulation layer 200. Similar to the first embodiment, insulation layer 200 is generally comprised of an oxide material. Insulation layer 200, as illustrated, additionally isolates a shielding structure 210, from gate structure 118.

Shielding structure 210 in this particular embodiment is defined by a trench 212 formed in semiconductor material 104, and having deposited therein a non-conductive material 214, in this particular embodiment being a dielectric material. It is anticipated by this disclosure that trench 212 alternatively may have formed therein an intermediate conductive material, in the form of a liner (not shown) between semiconductor material 104 and non-conductive material 214. Alternatively, non-conductive material 214 can be formed as an intermediate liner (not shown) between semiconductor material 104 and a conductive material deposited therein. In this instance the conductive material would be electrically isolated from both gate structure 118 and drain 106.

In this particular embodiment, the decreased gate-drain capacitance (C_{GD}) is a result of the increased dielectric thickness, as a result of shielding structure 210, over drain region 106. Trench 212 is fabricated using standard etching techniques, and then filled with non-conductive material 214. The use of a trench structure in device 100 allows the spacing between adjacent body regions 108 to be decreased further than with the use of a field oxide plug, as is previously known in the art. In this particular embodiment, trench 212 does not actual come in contact with first or second body regions 108. Channel and accumulation regions remain horizontal along the surface of semiconductor material 104.

The inclusion of shielding structure 210, and more particularly trench 212 and non-conductive material 214, provides for a decrease in the gate-drain capacitance, in generally the same manner as the first disclosed embodiment. More particularly, shielding structure 210 provides for the “shielding” of capacitance between active gate structure 118 and drain region 106, and thereby decreases the gate-drain capacitance (C_{GD}) without an increase in the total device ON-state resistance (R_{DSON}).

Device 100 is formed in conventional discrete MOSFET fabrication process. Shielding structure 210 is formed by first etching trench 212. This etching step can be done by conventional etch means. There is a considerable flexibility in the timing of the etch step for trench 212 during the fabrication process. The etching of trench 212 can occur at any point prior to the fabrication of gate 118 without incurring the additional process cost of repairing gate 118. Preferably, trench 212 is etched prior to the deposition of insulation layer 200. In this preferred embodiment, non-conductive material 214 is deposited therein trench 212 once the etching of trench 212 is complete. If trench 212 is formed subsequent to the fabrication of insulation layer 200, then non-conductive material 214 is preferably used to replace that portion of layer 200 lost during the etch of trench 212. To complete the fabrication of device 100 once trench 212 is filled, conventional MOSFET processing is used.

As is evident from the foregoing discussion, the present disclosure provides for a semiconductor MOSFET device in which included is a shielding structure for the purpose of decreasing gate-drain capacitance (C_{GD}) while maintaining total device ON-state resistance (R_{DSON}). The shielding structure disclosed is formed between the gate structure and the drain region. In a first embodiment, the shielding structure is formed as a dummy gate, having a surrounding active gate, and in a second embodiment, the shielding structure is formed as a trench having a non-conductive material formed therein.

Thus, it is apparent that there has been provided, in accordance with the invention, a semiconductor MOSFET device having a means for decreasing the gate-drain capacitance (C_{GD}) without a noticeable increase in total device ON-state resistance (R_{DSON}). Although the disclosure has been described and illustrated with reference to specific embodiments thereof, it is not intended that the disclosure be limited to these illustrative embodiments. Those skilled in the art will recognize that modifications and variations can be made without departing from the spirit of the invention. Therefore, it is intended that this disclosure encompass all such variations and modifications as fall within the scope of the appended claims.

1-15. (canceled)

16. A method of fabricating a power MOSFET device, comprising the steps of:
providing a semiconductor material having a first conductivity type, wherein the semiconductor material includes therein a drain region;
forming at least one body region of a second conductivity type in the semiconductor material;
forming at least one source region of the first conductivity type formed in each of the at least one body regions;
forming a shielding structure comprising a dummy gate deposited over a surface of semiconductor material for reducing the gate-drain capacitance; and
forming a gate electrode over the shielding structure, the gate electrode being insulated from the semiconductor material by an insulation layer.

17. A method of fabricating a power MOSFET device as claimed in claim 15 wherein the step of forming at least one body region includes forming a first body region and a second body region and the step of forming at least one source region includes forming a first source region and a second source region.

18. A method of fabricating a power MOSFET device as claimed in claim 15 further including a step of forming at least one contact region of the second conductivity type in each of the at least one body regions.

19. A method of Fabricating a power MOSFET device as claimed in claim 17 wherein the step of forming at least one contact region of the second conductivity type includes forming a first contact region and a second contact region.

20. A method of fabricating a power MOSFET device as claimed in claim 16 wherein the step of forming a gate electrode includes the step of forming a tiered gate structure surrounding the dummy gate.

21. A method of fabricating a power MOSFET device as claimed in claim 16 wherein the step of forming a gate electrode includes forming the gate structure to overlap the junction between the drain region and the at least one body region.

22-29. (canceled)

30. The method of claim 16, wherein the dummy gate is formed of a conductive material.

31. The method of claim 30, wherein the conductive material is selected from a group consisting of polysilicon, metal, polycides, and semiconductive material.

32. The method of claim 16 further comprising biasing the dummy gate.

33. The method of claim 16 further comprising patterning the dummy gate such that it does not overlap a junction between the drain region and each of the at least one body regions.

34. The method of claim 33 further comprising patterning the gate electrode such that it overlaps the junction between the drain region and each of the at least one body regions.
